(19) United States
(12) Patent Application Publication
(10) Pub. No.: US 2021/0013373 A1
(43) Pub. Date: Jan. 14, 2021

(54) Strain-relaxed InGaN-alloy template

(71) Applicant: National Technology & Engineering Solutions of Sandia, LLC, Albuquerque, NM (US)

(72) Inventor: Stephen R. Lee, Albuquerque, NM (US)

(21) Appl. No.: 16/505,993

(22) Filed: Jul. 9, 2019

(51) Int. Cl. H01L 33/12; H01L 33/06; H01L 33/16; H01L 33/22; H01L 33/32; H01L 33/00

(52) U.S. Cl. CPC H01L 33/12; H01L 33/06; H01L 33/16; H01S 5/34333; H01L 33/32; H01L 33/0075; H01L 33/22

(57) ABSTRACT

The invention is directed to a method for fabricating strain-relaxed InGaN-alloy templates with higher indium compositions, reduced threading-dislocation densities, improved surface morphologies, and lowered point-defect densities. The method employs nanopatterns fabricated onto the surface of GaN-based templates or bulk-GaN substrates using conventional semiconductor processing. The nanopatterns are specifically designed to enable maskless nanoepitaxial growth of InGaN alloys while simultaneously promoting combined elastic and plastic strain relaxation during nanoepitaxy of InGaN alloys in a manner that raises alloy compositions and reduces defect formation. These templates enable subsequent growth of III-Nitride optoelectronics operating at wavelengths spanning most of the visible-light spectrum while simultaneously enabling higher efficiencies than attained using strain-relaxed InGaN alloys grown by conventional planar heteroepitaxy.

### STATEMENT OF GOVERNMENT INTEREST

This invention was made with Government support under Contract No. DE-NA0003525 awarded by the United States Department of Energy/National Nuclear Security Administration. The Government has certain rights in the invention.

### FIELD OF THE INVENTION

The present invention relates to light-emitting diodes and, in particular, to a strain-relaxed InGaN-alloy template for growing high-indium-content InGaN light-emitting diodes.

### BACKGROUND OF THE INVENTION

The ongoing revolution to replace conventional incandescent and fluorescent lighting with more energy-efficient solid-state lighting (SSL) currently relies on lamps comprised of lower-indium-content (x≤0.18) InₓGa₁₋ₓN quantum-well (QW) light-emitting diodes (LEDs) that optically pump various light-emitting phosphors. In this configuration, white-light illumination is supplied by mixing the LED's directly emitted blue (or violet) light with the pumped light output by the phosphors, which are selected to emit in the green, yellow, and/or red spectral ranges. This pumped-phosphor approach limits the maximum attainable efficiency of SSL because of the Stokes-shift energy-difference losses that occur when higher-energy blue (or violet) photons pump the phosphors to obtain the lower-energy green, yellow, or red photons needed to create white light. To eliminate the Stokes-shift energy losses (which manifest as heating of the phosphor and its encapsulants), color mixing schemes have been proposed that utilize arrays of LEDs wherein each LED directly emits colored light at one of the RGB or RGBY (red-green-blue, and often, -yellow) wavelengths needed for high-quality white illumination. See M. H. Crawford, IEEE J. Sel. Top. Quantum Electron. 15, 1028 (2009).

The main materials challenge preventing the above-described higher-efficiency direct-LED-color-mixing approach is the well-known green (or green-yellow) gap in LED-light-emission efficiency. As shown in FIG. 1, state-of-the-art InₓGa₁₋ₓN-QW LEDs rapidly decline in measured external quantum efficiency as the LED emission wavelength increases from the violet/blue range (λ=420-500 nm) towards the longer-wavelength green/yellow/red=500-630 nm) portions of the visible-light spectrum. This strong decrease in external quantum efficiency with increasing InGaN-QW emission wavelength arises from the poor and declining internal quantum efficiency (IQE) of the very thin, highly strained, InGaN-alloy heterolayer materials used to make the QWs. The term “green gap” arises because a separate semiconductor-alloy-materials system already exists (AlGaInP) for fabricating relatively efficient QWs emitting at orange-to-red wavelengths. Thus, it is primarily the severe QW-LED efficiency gap in the green-to-yellow portion of the visible spectrum that prohibits manufacture of ultra-high efficiency white-lighting based on direct-LED color mixing. See M. R. Krames et al., J. Displ. Tech. 3, 160 (2007); U.S. Pat. No. 9,978,904 to M. R. Krames et al., issued May 22, 2018; and M. H. Crawford, IEEE J. Sel. Top. Quantum Electron. 15, 1028 (2009).

There are several possible physical causes for the extreme green-to-yellow-to-red decline in the IQE of InGaN-QW heterolayers. These causes all tie to the fact that the fabrication of InₓGa₁₋ₓN-QWs with increasing emission wavelengths requires corresponding increases in the InN mole-fraction of the InGaN-alloy that forms the QWs. The most important phenomena thought to be responsible for declining IQE are (i) increasing InGaN—GaN lattice-mismatch-driven introduction of misfit dislocations, which are nonradiative carrier-recombination centers; (ii) increasing thermal decomposition of the InGaN alloys, which require ever lower growth temperatures to achieve higher In compositions; (iii) increasing incorporation of non-radiative recombination centers such as point defects and impurities because of these required temperature decreases; (iv) increasingly strain-limited incorporation of In into InGaN alloys when grown pseudomorphically (coherently strained) on the typically used GaN templates or substrates, which requires yet a further lowering of growth temperatures than would be required for unstrained lattice-matched growth; (v) increasing piezoelectric fields for InGaN/GaN MQWs when grown on polar or semi-polar GaN, which decreases the overlap of electron and hole wavefunction within the QWs, again reducing radiative efficiency; and (vi) the increasing possibility of phase separation as the InGaN-alloy compositions move deeper into the miscibility gap. See P. Costa et al., Phys. Status Solidi A 203, 1729 (2006); P. M. Costa et al., MRS Proceedings 892, (2005); D. Holec et al., J. Cryst. Growth 303, 314 (2007); A. Cremades et al., Mater. Sci. Eng. B 80, 313 (2001); Y. Kangawa et al., Phys. Status Solidi C 0(7), 2575 (2003); J. Ou et al., Jpn. J. Appl. Phys. 37(6A), L633 (1998); E. Thrush et al., J. Cryst. Growth 248, 518 (2003); T. Yayama et al., Jpn. J. Appl. Phys. 48, 8004 (2009); Z. Liliental-Weber et al., J. Electron. Mater. 30, 439 (2001); S. Pereira et al., Appl. Phys. Left. 80, 3913 (2002); U. T. Schwarz and M. Kneissl, Phys. Status Solidi (RRL) 1, A44 (2007); P. Waltereit et al., Nature 406, 865 (2000); and I.-H. Ho and G. Stringfellow, Appl. Phys. Lett. 69, 2701 (1996).

The underlying mechanism driving all of these phenomena is the large mismatch between the In—N and Ga—N atomic bonds in the InGaN alloys. The large bond-length mismatch produces continuum elastic strains when the InGaN alloys are grown pseudomorphically on planar GaN surfaces, which drives phenomena (i), (iii), and (v). Moreover, the bond-length mismatch is accompanied by a correspondingly large bond-energy mismatch that underlies phenomena (ii), (iv), and (vi). Thus, for InGaN-QWs grown coherently strained on GaN, all six of the cited phenomena will tend to increase in severity as the QW-emission wavelength and the required InN mole-fraction of the InGaN-alloys concomitantly increase.

While various approaches for addressing the green-gap problem have been pursued, a promising approach would be to grow the InGaN-QWs on substrates that have greatly reduced (or no) lattice-mismatch compared to that of the existing scheme where InGaN-QWs are pseudomorphically grown on planar GaN. For lattice-mismatched growth of InGaN alloys on GaN substrates, several methods for reducing the lattice-mismatch have been studied, implemented, and/or patented. See, for example, U.S. Pat. No. 8,143,154 to Chua et al., issued Mar. 27, 2012; U.S. Pat. No. 7,250,359 to Fitzgerald et al., issued Jul. 31, 2007; U.S. Pat. No. 8,866,126 to Ohta et al., issued Oct. 21, 2014; U.S. Pat. No. 9,159,553 to Ohta et al., issued Oct. 13, 2015; U.S. Pat. No. 7,727,333 to Syrkin et al., issued Jun. 1, 2010; U.S. Pat. No. 9,978,904 to M. R. Krames et al., issued May 22, 2018; U.S. Pat. No. 7,655,960 to Nakahata et al., issued Feb. 2, 2010; U.S. Pat. No. 8,343,782 to Letertre, issued Jan. 1, 2013; U.S. Pat. No. 8,642,443 to Boulet, issued Feb. 4, 2014; and U.S. Pat. No. 9,343,626 to Debray et al., issued May 17, 2016.

For instance, one can perform heteroepitaxy of relatively thick, strain-relaxed, InGaN-alloy buffer layers directly onto planar GaN (or sapphire) templates using hydride vapor-phase epitaxy, metal-organic vapor phase epitaxy (MOVPE), or molecular-beam epitaxy (MBE). See P. Costa et al., Phys. Status Solidi A 203, 1729 (2006). Such methods may also utilize well-known variations (often first-developed for earlier semiconductor-materials systems) such as compositional grading or the use of various types of interlayers inserted into thick buffer layers to reduce or manipulate its defects or surface topography. See U.S. Pat. No. 7,250,359 to Fitzgerald et al., issued Jul. 31, 2007. The primary shortcoming of these traditional methods when applied to thick InGaN/GaN heteroepitaxy are high threading-dislocation densities, low achievable alloy compositions, unusable surface morphologies, and/or thermal decomposition of the alloy. InGaN-alloy layers grown thin enough to avoid these problems are not strain relaxed and therefore fail to solve the underlying lattice-mismatch problem between the overlying InGaN-alloy QW layers and the underlying GaN template (or substrate).

A second group of solutions utilize selective-area epitaxy (SAE) or epitaxial lateral overgrowth (ELO) of relatively thick, strain-relaxed InGaN-alloy buffers onto masked GaN templates. See J. Song et al., Nanotechnology 25, 225602 (2014). The mask is typically a very thin dielectric or metallic film that has a large-area array of patterned apertures (holes or stripe-like trenches) that expose the underlying GaN to the growth ambient. These patterned features can have a lateral size and periodicity that can be fabricated at either micrometer-, submicrometer-, or nanometer-size length scales. In this case, a primary shortcoming is increasingly unintended chaotic nucleation of InGaN-alloy crystallites onto the required patterned-mask layer as the InGaN-alloy composition is raised; this failure of mask selectivity tends to limit achievable InN mole fractions in the InGaN-alloys to less than x˜0.10. The above-cited research by J. Song et al. has sought to push this limit upwards to some degree by using advanced, pulsed-growth techniques that alter surface transport and desorption of growth species. Moving beyond growth on commonly available GaN templates, another way to solve the mismatch problem to InGaN-alloys is to seek an entirely different type of substrate that has bulk lattice parameters that are intrinsically better lattice-matched to the InGaN-alloys of interest. Such lattice-matched substrates that are simultaneously compatible with existing manufacturable, large-scale heteroepitaxial growth methods remain rare or undiscovered; though some attempts to develop such alternative bulk substrates have been made.

Most SSL LEDs are presently grown on GaN templates having a polar (0001) surface orientation. See M. H. Crawford, IEEE J. Sel. Top. Quantum Electron. 15, 1028 (2009). Another way to partly reduce the green-yellow gap is to use GaN substrates having either a nonpolar or a semipolar surface orientation. Because of the differing atomic reconstructions occurring at the nonpolar and semipolar surfaces of GaN, these surfaces offer the possibility for increasing indium incorporation during heteroepitaxy of InGaN alloys directly onto GaN—even though intrinsically problematic lattice-mismatch strains still remain present. Unlike the other approaches discussed above, the non/semipolar strategy does not generally seek to directly reduce or remove the effects of lattice mismatch between InGaN alloys and GaN templates or substrates. Even so, facile anisotropic strain relaxation along a single in-plane direction occurs in thicker InGaN-alloy layers grown on planar, semipolar-oriented GaN substrates, where dislocation slip occurs on the inclined basal planes formed by the semipolar-surface orientation and wurtzite crystal structure. See A. E. Romanov, et al., J. Appl. Phys. 109, 103522 (2011). Notably, consideration of this one-dimensional (1D) relaxation phenomenon, and pursuit of techniques to extend the relaxation to the orthogonal in-plane direction and realize uniform strain relaxation, played a role in development of the presently reported methods for achieving strain-relaxed InGaN.

The problems posed by heteroepitaxial thin-film growth onto lattice-mismatched substrates has long been encountered across a wide variety of materials systems beyond the field of III-nitride semiconductors. Thus, many additional research studies have been published and patents granted in a broad effort to improve the materials quality resulting from lattice-mismatched heteroepitaxy. See U.S. Pat. No. 9,318,326 to Von Kanel et al., issued Apr. 19, 2016; and U.S. Pat. No. 6,835,246 to Zaidi, issued Dec. 28, 2004.

Various methods exist for controlling threading dislocation during GaN heteroepitaxy on sapphire or SiC. Even now, highly perfect bulk-GaN substrates remain relatively expensive to produce and thus do not dominate in the SSL market. Instead, the SSL market prefers use of few-micron-thick GaN-template films grown extremely lattice-mismatched on inexpensive bulk-sapphire or bulk-SiC substrate wafers. Highly optimized multi-step growth methods have been developed that take advantage of the uniquely tunable, facet-selective growth modes offered by GaN. These novel methods readily provide GaN templates with acceptably low threading-dislocation densities (˜5×10⁸/cm²) and with excellent epi-ready surface morphologies. Such templates are very well suited to the heteroepitaxy of the highly efficient violet- and blue-emitting InGaN-based QWs that currently dominate SSL (growth of these QWs succeeds because the InGaN-alloy's in-plane lattice-mismatch strain (to GaN) needed to reach the violet- and blue-emission regimes remains just within a tractable range suitable for conventional planar epitaxy, εₓₓ≤2%). Notably, growths of thick, strain-relaxed, InGaN-alloy template layers directly onto sapphire or SiC (in a manner similar to that for GaN templates) fail because reduced-temperature InGaN-alloy growths do not offer the same highly tunable, facet-selective growth modes that GaN offers. No amount of process optimization can compensate for the fundamentally different growth behavior of the alloys.

While InGaN-QW-based LEDs can tolerate the moderately high GaN-template threading-dislocation densities described above (˜5×10⁸/cm²)—without significant reductions in IQE or in device lifetime—InGaN-QW-based laser diodes (LDs) cannot because the LD's operating lifetimes rapidly decline in the presence of the threading dislocations. Before high-quality bulk-GaN became available, this problem prevented successful LDs and thus motivated the widespread active development of multiple substrate-patterning-based methods for growing very-low threading-dislocation-density GaN templates on sapphire or SiC. The wide variety of methods that have been pursued can be broadly grouped into three basic schemes.

The first scheme, often called “epitaxial lateral overgrowth” (ELO) employs SAE of GaN onto a defective, planar GaN template that is covered with a patterned mask that selectively exposes the GaN to further growth. See B. Beaumont et al., Phys. Status Solidi B 227, 1 (2001); and U.S. Pat. No. 6,325,850 to Beaumont et al., issued Dec. 4, 2001. For a related implementation in non-III-nitride materials, see also U.S. Pat. No. 8,034,697 to Fiorenza et al., issued Oct. 11, 2011. The described research to grow strain-relaxed InGaN alloys by SAE and ELO methods originates from this earlier work to reduce GaN defectivity when grown on sapphire.

The second scheme resembles ELO, but the selective mask is now placed onto a GaN surface that has been prepatterned by etching to be nonplanar; a patented version of this second scheme is called “pendeoepitaxy”. See U.S. Pat. No. 6,261,929 to Gehrke et al., issued Jul. 17, 2001. Many subsequent patents have similarly invoked some form of surface-feature patterning combined with selective growth masking, followed by heteroepitaxial growth.

The third scheme resembles the second scheme, but uniquely does away with the growth mask completely so that the lattice-mismatched heteroepitaxial growth proceeds in a completely maskless fashion. In this maskless approach, the geometry of the patterned surface is selected such that the patterned surface itself serves as an adequate virtual mask—while at the same time enabling the same lattice-mismatch accommodation and defect filtering seen in the previous mask-enabled SAE, ELO, and pendeoepitaxy methods. This last approach is called “cantilever epitaxy” (CE). See U.S. Pat. No. 6,599,362 to Ashby et al., issued Jul. 29, 2003.

### SUMMARY OF THE INVENTION

The present invention is directed to a strain-relaxed InGaN-alloy template and a method for fabricating a strain-relaxed InGaN-alloy template, comprising nanopatterning a GaN substrate and maskless nanoepitaxially growing an InₓGa₁₋ₓN-alloy template layer onto the nanopatterned GaN substrate. The indium elemental composition, x, can be between 0.06 and 0.6 and, preferably, between 0.15 and 0.4, for applications involving visible wavelengths of light beyond blue (˜470 nm). The lateral width, height, spacing, shape, and crystallographic orientation of the nanopatterned surface structures, as well as the thickness of the InₓGa₁₋ₓN-alloy template layer, can be jointly selected to relax the strain in the InₓGa₁₋ₓN alloy while maintaining a useful surface morphology and managing threading-dislocation introduction and termination.

In general, the nanopatterns of interest comprise either one-dimensional arrays of parallel nanowalls, or two-dimensional arrays of nanoposts. To facilitate growth of a strain-relaxed InₓGa₁₋ₓN-alloy template at a specified composition, the individual surface structure (i.e., nanowall or nanopost) width, w, can be selected to be no more than twice the minimum local InGaN template layer thickness, tₘ, that is likely to produce the onset of misfit-dislocation glide within the individual InGaN/GaN nanostructures. To provide a physically reasonable estimate, tₘ is likely to be no greater than the kinetically limited critical thickness, hₖ(x), for the onset of strain relaxation when the same-composition alloy is grown on planar GaN having the same crystallographic surface as that presented by the top of the surface structure.

These two specified conditions [w<2tₘ and tₘ<hₖ(x)] combine to give a useful nanopattern-design condition, w<2hₖ(x), that ties the intended width of the individual surface structures to the coherent-alloy composition (and its lattice mismatch strain on GaN). If this condition is met, the InGaN alloy will tend to grow thick enough to adopt a substantially nonplanar nanostructured shape prior to the onset of any dislocation motion, with the nonplanar shape of the InGaN alloy giving rise to an enhanced, highly inhomogeneous stress field centered about the local heterointerface. Through this approach, the surface structure width can be selected in a manner that promotes timely, more effective glide of misfit dislocations just as they are most likely to begin entering the isolated InGaN/GaN nanostructures.

By limiting the surface structure width to the specified strain-relaxation regime, practical limits on the InGaN-alloy nanoepitaxial thicknesses can be correspondingly defined (below) while still obtaining a high degree of strain relaxation. A second primary benefit thereby obtains because the resulting InGaN-alloy film thicknesses can be limited to submicron and nanometer thicknesses. These smaller thicknesses enable shorter growth times compatible with the well-known, tenuous thermal stability of InGaN-alloys, particularly as their composition rises to larger InN mole fractions.

In a further aspect of the invention, the initial onset of lateral coalescence of the growing template can be chosen to occur at an average nanoepitaxial thickness, hᵢₙᵢₜ, that equals or exceeds the width of the original surface structure. This condition, hᵢₙᵢₜ≥w, allows the InGaN-alloy structure growing onto the upper region of each surface structure to become thick enough prior to coalescence to undergo substantial elastic and/or plastic relaxation, thereby relieving most of the elastic strain initially imposed by coherent epitaxy onto the GaN surface structure. Completion of the strain relaxation process prior to coalescence is desirable to prevent recovery of the coherent elastic strain upon coalescence. After actual coalescence during template growth, a bit more alloy thickness can be grown on top to improve surface morphology, homogenize composition, and stabilize to a final (residual) strain state.

InGaN alloys often have generally similar lateral (Vₓ) to vertical (V_{y}) growth rate ratios near to Vₓ/V_{y}˜1 when grown by vapor-phase deposition methods onto a nanopatterned surface. Geometric consideration of the growth-rate ratio gives the condition hᵢₙᵢₜ˜(s+w)/2, where s is the spacing that separates adjacent surface structures. Combining this with the previous condition needed to obtain relaxation, the criterion s≥w is obtained.

A further aspect of the invention is directed to maskless cantilever epitaxy of InGaN alloys. In general, the depth of the trenches, d (separating the adjacent surface structures of this same height), can be approximately equal to, or greater than s, such that d≥s. For InGaN alloys grown with similar lateral-to-vertical growth rates, this geometry implements a “virtual-mask” because any vapor-phase alloy precursors flowing into the trenches separating the surface structures will lead to growth on the surface-structure's sidewalls, or at the trench bottoms. Deposition there prevents interference with coalescence processes proceeding in growth regions near to and on the top of each surface structure. This virtual masking supplants the need for a selective-area hard-mask, as required to prevent unwanted InGaN-alloy deposition onto selected areas of nanopatterns used in alternative methods, such as SAE.

The InₓGa₁₋ₓN-alloy template layer can be coalesced or uncoalesced on the nanopatterned GaN substrate. Additionally, the above described considerations can be applied to any of the polar, semipolar, and nonpolar crystallographic growth surfaces of GaN.

The present invention specifically draws upon the described design criteria to produce nanopatterns and enable maskless, cantilever epitaxy of InGaN alloys onto arrays of GaN surface structures in a manner enabling growth of improved strain-relaxed InGaN-alloy templates. To perform patterned heteroepitaxial growth of relatively thick, strain-relaxed InGaN-alloys, the maskless feature of CE is pivotal because of the already noted tendency of InGaN-alloys to form unwanted nuclei and crystallites on most commonly used growth-mask materials. See J. Song et al., Nanotechnology 25, 225602 (2014). The resultant strain-relaxed InGaN-alloy templates are well-suited for subsequent growth of InGaN-alloy optoelectronic-device active regions (for example, multiple quantum wells). For example, the InGaN-alloy templates can have thicknesses in the range 150 nm (if uncoalesced) to 600 nm (if grown well past coalescence), with typical InGaN compositions reaching x=0.20-0.25. These compositions are at least 1.5× larger than those of pseudomorphic planar heteroepitaxial layers grown under identical ambient conditions. InGaN MQWs grown on these templates have elevated indium compositions in the range x=0.33-0.40, which enables intense visible-light emission at wavelengths in the range 550-610 nm. Therefore, these InGaN-alloy templates are suited for use far into the visible-wavelength range (green, yellow, red) and perhaps even into the infrared. These templates, and the increased-indium-content optoelectronic devices subsequently grown upon them, have potentially wide applicability in the SSL and solar-PV global markets.

### BRIEF DESCRIPTION OF THE DRAWINGS

The detailed description will refer to the following drawings, wherein like elements are referred to by like numbers.

FIG. 1 is a graph showing the green gap in high-power light-emitting-diode (LED) energy-efficiency performance. The illustrated external quantum efficiencies are for a 350 mA drive current into 1 mm² LED die operating at 25° C. The 2007 data are reproduced from Krames et al.; the 2018 data are calculated from published product specifications from leading commercial manufacturers for the highest performing products offered. See M. R. Krames et al., J. Displ. Tech. 3, 160 (2007).

FIGS. 2A-2C are illustrations of a method for fabricating a strain-relaxed InGaN-alloy template layer on a nanopatterned GaN substrate. The figures show InGaN-alloy heterolayer stresses for different alloy-layer thicknesses of growth on GaN nanowalls. Lattice-mismatch stresses acting perpendicular, σₓₓ, and parallel, σ_{yy}, to the nanowalls will cause differing elastic and plastic responses that evolve with the alloy-layer thickness. FIG. 2A illustrates purely elastic stresses developing at early growth times. FIG. 2B illustrates misfit-dislocations forming at later growth times. FIG. 2C illustrates the completed InGaN-alloy template, with relaxation of stress acting parallel to the nanowalls and with elastic relaxation of stresses acting perpendicular to the nanowalls.

FIGS. 3A-3E are illustrations of the purely elastic response of InGaN-alloy deposited coherently onto GaN. FIG. 3A shows planar InGaN film growth on a conventional GaN wafer, where film strain is highly uniform excepting very small regions nearest the wafer edge. FIGS. 3B-3E show hypothetical, dislocation-free, columnar InGaN growths onto the upper surface of GaN nanowalls or nanoposts. The speckled area indicates the region of peak inhomogeneous stress and strain within the elastically coupled film and substrate. The illustration shows anisotropic, columnar growth for simplicity; similar boundaries will hold for isotropically grown structures when deposited onto the upper region of the initial surface structures.

FIG. 4 is a graph that compares the thermodynamics-based Matthews-Blakeslee (MB) critical thickness, h_{c}, for misfit dislocation glide to the kinetically limited critical thickness (black symbols), hₖ, seen in previous planar-growth experiments. The h_{c} values are plotted versus InₓGa₁₋ₓN alloy composition, x, for growths on (0001) GaN. The thermodynamic critical radius, r_{c}, for misfit dislocation glide in an InGaN—GaN core-shell nanowire is shown in comparison to the MB h_{c} for planar layers.

FIG. 5A illustrates a simplified rectangular-domain model used to parameterize nanowall coalescence. FIG. 5B is a graph of the relative coalescent layer thickness (h/w) vs averaged lateral/vertical growth-rate ratio (Vₓ/V_{y}) and parameterized in terms of the nanopattern fill-factor (f). Columnar (left), quasi-isotropic (center), and lateral (right) patterned-growth regimes are shown.

FIG. 6 is a cross-sectional-view SEM/secondary electron image of cleaved InGaN/GaN nanowalls on (0001) GaN. For InGaN growth on an as-fabricated GaN nanowall with a fill-factor near 40%, sidewall growth of InGaN is increasingly minimal at trench depths d exceeding 1s to 2s.

FIG. 7A is an oblique-plan-view (30° off surface normal) SEM image of the top pyramidal surfaces of InGaN/GaN nanowalls oriented parallel to <10-10> on (0001) GaN. FIG. 7B is an SEM image for nanowalls oriented parallel to <11-20> on (0001) GaN.

FIG. 8A is a cross-sectional high-angle annular dark-field (HAADF) scanning-transmission electron microscopy (STEM) image of a 600-nm-thick InGaN buffer and 3-period InGaN MQW grown on a <11-20>-oriented GaN nanowall on (0001) GaN. FIG. 8B is a cross-sectional-view STEM/EDS InGaN-alloy composition map for the 600-nm-thick InGaN buffer and 3-period InGaN MQW grown on a <11-20>-oriented GaN nanowall on (0001) GaN. FIG. 8C is an enlarged view of the tip-region of the intersecting (10-11) nanopyramidal facets showing individual QWs and a GaN cap. FIG. 8D is an extracted line profile of the In concentration of the MQW.

FIG. 9A is a room-temperature (RT) photoluminescence (PL) spectrum of a 3-period InGaN-MQW grown on a coalesced InGaN/GaN nanowall template. FIG. 9B is a RT PL spectrum of a 5-period InGaN/GaN MQW calibrated reference sample. FIG. 9C is a graph of the measured power-dependent radiative efficiencies of an InGaN/GaN nanowall sample (circles) obtained by measuring the PL integrated intensity relative to the calibrated reference sample. The independently measured power-dependent radiative efficiency of the calibrated reference sample is also shown (triangles).

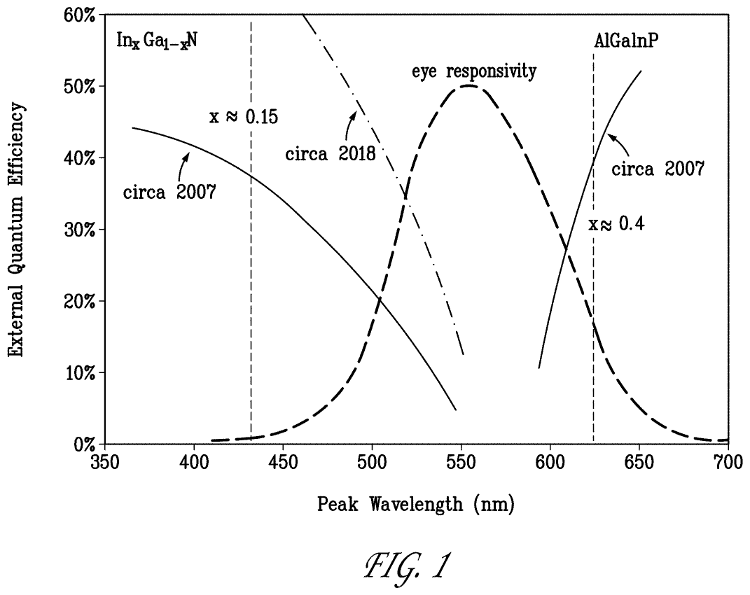

### DETAILED DESCRIPTION OF THE INVENTION

The present invention is directed to methods for fabricating strain-relaxed InₓGa₁₋ₓN-alloy template layers with technologically relevant compositions, x, in the range 0.06<x<0.6. Templates made by the methods of the present invention have greatly reduced threading-dislocation densities, reduced point-defect content, and technologically useful surface morphologies compared to conventional strain-relaxed InGaN-alloy layers of similar compositions when fabricated by heteroepitaxial growth onto planar GaN templates.

### Fabrication of Strain-Relaxed InGaN-Alloy Template

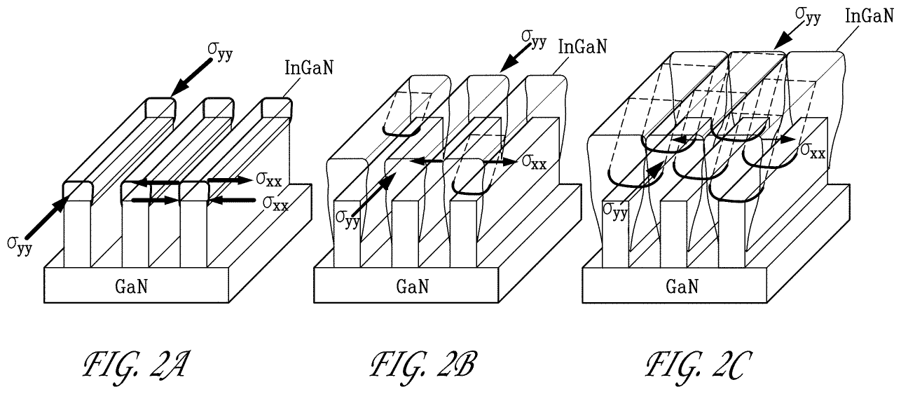

The fabrication method is partially illustrated in FIGS. 2A-C. In simplest terms, there are two major steps for fabricating a strain-relaxed InGaN-alloy template upon a commercially available GaN or similar substrate.

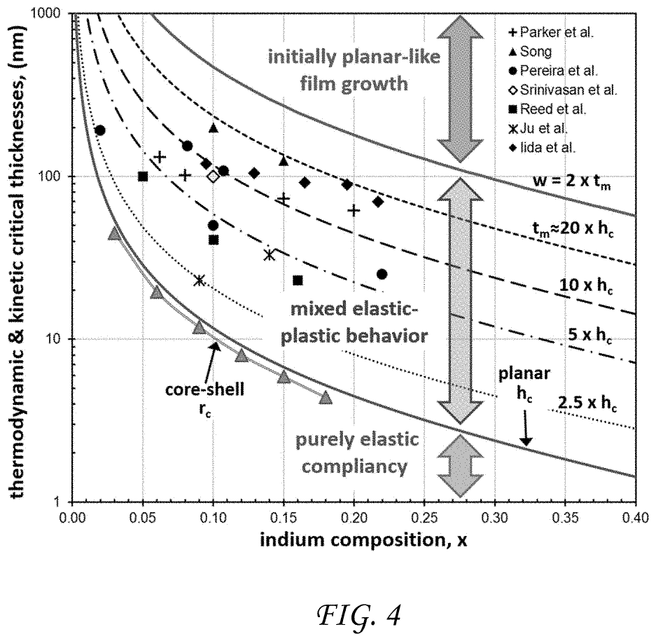

The first fabrication step comprises nanopatterning of a GaN or similar substrate. An array of surface structures is fabricated on the originally planar surface of the substrate. The GaN substrate wafer can be selected with any of the surface orientations (polar, nonpolar, or semipolar) typically used to make III-nitride optoelectronic devices; the precise orientation of the surface can be either near-vicinal or intentionally miscut. For example, the starting GaN substrate can be either a few-micron-thick GaN film pregrown on either a sapphire or SiC wafer, or a bulk GaN substrate; the substrate can have InGaN-alloy and/or other III-nitride thin-film layers grown upon it prior to patterning or it can simply be the as-fabricated substrate. For example, the surface structures can comprise an array of parallel nanowalls (e.g., prismatic or rectangular ridges or raised stripes) separated by linear trenches. To facilitate InGaN-alloy growth, the individual elements forming the array of surface structures will typically have submicron-sized lateral widths that are selected to lie below the boundary shown in FIG. 4 (uppermost plotted curve) delineating the planar-like growth and the partially compliant growth regimes. As an example, the nominal shape of the etched nanowalls can comprise linear trenches that act to separate flat-topped raised stripes of unetched GaN, as shown schematically in FIGS. 2A-2C. Replication of the etched trenches across a significant lateral area of the substrate wafer defines an array of parallel GaN nanowalls that simultaneously serve as both a virtual mask and as an array of locally elevated growth surfaces during subsequent heteroepitaxy. However, other surfaces structures, such as nanoposts (sometimes referred to as “nanorods” or “nanowires”), can also be used. These nanoposts can have a variety of cross-sections (e.g., circular or square) and the nanopost arrays can have a variety of lattice types (e.g., square or hexagonal). Hereafter, the etched array of submicron surface structures is referred to as a “nanopattern.” The heteroepitaxial growth of the template layer onto the nanopattern is referred to as “nanoepitaxy.”

The fabrication of the submicron-dimensioned nanopattern onto the GaN-substrate surface can be performed using any suitable lithographic process. Typical lithographic processes include UV-based projection lithography, UV-laser-based interferometric lithography (IL), or nanoimprint lithography; these and similar methods are highly manufacturable and feature usefully high spatial resolution in the submicron and nanometer ranges of most interest for InGaN-alloy nanoepitaxy. The lithographically defined photoresist nanopattern can be transferred into the GaN surface using standard, well-known, semiconductor processing methods, wherein a dry plasma-based etching process, perhaps in combination with some wet-etching process, is used to transfer (i.e., etch) the selected nanopattern into the GaN surface to a specified depth, thus forming the trench-separated elevated surface structures described above. The bounding trench domains can have nominally vertical sidewalls, though this is not specifically required.

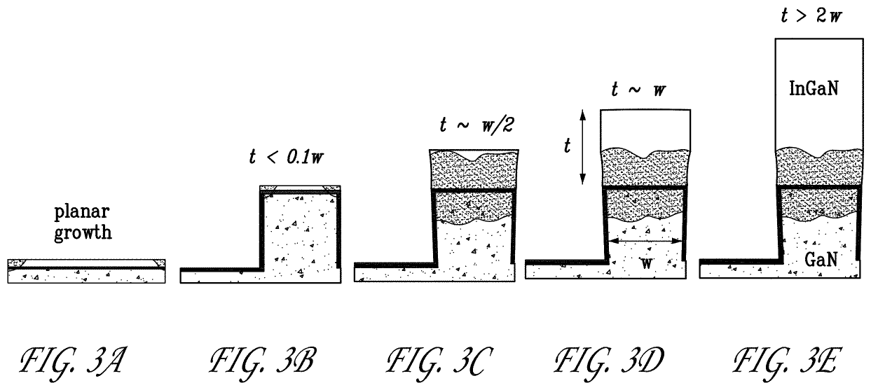

The second fabrication step comprises maskless nanoepitaxy of InGaN alloys onto the nanopatterned GaN substrate. To complete the fabrication of a strain-relaxed InGaN-alloy template, an elastically thick and partially (or fully) compliant layer of InGaN alloy is grown onto the nanopatterned substrate surface by a conventional means such as metal-organic vapor-phase epitaxy (MOVPE; aka MOCVD), hydride vapor-phase epitaxy (HVPE), plasma-assisted molecular-beam epitaxy (MBE), or some other type of MBE or chemical-vapor deposition (CVD). The terminology, “elastically thick”, is defined relative to width of the individual nanopatterned features, for example, the width of the nanowalls (or the diameter of the nanoposts), where the elastically thick regime is taken to be an average, uncoalesced, nanoepitaxial layer thickness, t, that exceeds the half-width, w/2, as seen schematically in FIGS. 3C-3E. The composition of this partially or fully compliant nanoepitaxial InGaN-alloy layer can be either constant, continuously varying, and/or step-wised varying. The as-grown spatially averaged composition can fall within the previously specified range of technological importance, 0.06<x<0.6, and preferably in the green-gap range of 0.15≤x≤0.4. Fully or partially strain-relaxed InGaN-alloy templates having compositions within this range are highly suitable for optoelectronic, photovoltaic, and electronic applications, but are difficult or impossible to grow with suitable quality using existing methods—particularly so as the In composition in the InGaN alloy rises, causing a corresponding rise in the lattice-mismatch-induced coherency strain to GaN.

Therefore, the invention can further comprise growing a lattice-matched InGaN alloy on the InGaN-alloy template layer. The lattice-matched InGaN alloy can be grown by a high-growth-rate method, such as hydride vapor-phase epitaxy; alternatively, the lattice-matched alloy can be grown by a bulk-grown approach, such as amonothermal crystal growth. Further, the GaN substrate can be removed to provide a free-standing wafer of InGaN alloy. An InGaN-alloy multiple quantum well structure or InGaN-alloy epitaxial optoelectronic-device structure can be grown on the InGaN-alloy template layer.

The unique qualities of the high-indium-composition, semi-compliantly grown InGaN-alloy template layer arise from the specific geometric characteristics and crystallography of the fabricated nanopatterns onto which the selected nanoepitaxy is performed. Nanopattern geometries favorable for maskless nanoepitaxy of InGaN alloys and required characteristics of these nanopatterns are described in detail below.

### Nanostructure Feature Width

FIGS. 2A-2C show an approximate GaN-nanowall growth geometry and a notional evolution of an InGaN-alloy growth front, the associated evolution of epitaxial-layer stresses perpendicular (σₓₓ) and parallel (σ_{yy}) to the nanowalls, and the resulting elastic and plastic strain-relaxation that occurs as growth proceeds. Lattice-mismatch stresses acting perpendicular, σₓₓ, and parallel, σ_{yy}, to the nanowalls will cause differing elastic and plastic responses that evolve with the alloy-layer thickness. As shown in FIG. 2A, purely elastic stresses develop at early growth times. Compressive stresses exist at the interface between the top surface of the GaN nanopattern and the InGaN-alloy growth. Tensile stresses exist at the InGaN-alloy growth front. As shown in FIG. 2B, misfit-dislocations are shown forming to relieve only the lattice-mismatch strains/stresses σ_{yy} acting parallel to the nanowalls. As shown in FIG. 2C, the completed dislocation array relaxes σ_{yy} acting parallel to the nanowalls, and purely elastic deformation acts to relieve only the strains/stresses σₓₓ acting perpendicular to the nanowalls.

It is emphasized here that the described ideal partitioning of plastic and elastic strain relief along directions parallel and perpendicular to the nanowalls in FIGS. 2A-C is hypothetical and for illustration purposes only, although it may obtain in some select real-world cases. For a given actual growth condition, the specific slip systems that activate, the alloy composition, the shape evolution and facet-growth rates of the alloy, and the extent of plastic versus elastic strain relief (along various competing in-plane nanopattern directions) will all be strongly influenced by the selected nanopattern geometry, the crystallographic orientation of the GaN surface, and the in-plane orientation and layout of the nanowalls or nanoposts comprising the nanopattern. In the example below, trenches formed on a (0001) GaN surface are assumed, with the nanowalls oriented parallel to either <10-10> or <11-20> directions. The evolution of nanoepitaxial stresses and their dependence on wall-width, w, wall-spacing, s, and trench-depth, d, of the nanowall-arrays are described below.

Taking w to represent the nanostructure width and taking t to represent the local characteristic layer thickness of the InGaN alloy, FIGS. 3A-3E conceptually illustrate the dislocation-free, purely elastic response of InGaN-alloy deposited coherently onto a GaN substrate. FIG. 3A shows planar InGaN film growth on a conventional GaN wafer, where film strain is highly uniform excepting very small regions nearest the wafer edge. FIG. 3B shows quasi-planar growth, with the onset of strain inhomogeneity at t˜0.1w. As inferred from St. Venant's principle, the film experiences maximally inhomogeneous elastic strain at a thickness of t˜w/2, as shown in FIG. 3C. See S. P. Timoshenko and J. N. Goodier, Theory of Elasticity, 3^{rd} Edition (McGraw-Hill, Singapore, 1970 pp 39-40 for a discussion of St. Venant's principle. A patterned alloy growth that reaches this thickness without relaxing via misfit dislocations would be near a (hypothetical) state of maximum inhomogeneous elastic strain (and hence, stress). As shown in FIGS. 3D and 3E, the upper region's strain decreases at t˜w, and approaches elastic equilibrium at t>2w. The as-grown lattice-mismatched alloy-thickness regime of particular interest herein is t≥w/2. One thus sees in FIGS. 3A-3E the motivation for the earlier-defined terms “elastically thick” and “compliant,” which designate as-deposited InGaN-alloy-layer thicknesses (where the thickness is measured at the topmost and/or upper-sidewall surfaces of the nanopattern) that initially reach or exceed approximately one-half of the characteristic width (or characteristic diameter) of the individual surface structures forming the nanopattern array. By considering this conceptual evolution of the inhomogeneous strain field with nanoepitaxial layer thickness, one can consider which layer thicknesses may be best suited for the onset of misfit dislocation introduction, as discussed next.

Given a specific InₓGa₁₋ₓN composition, x, for an alloy initially growing coherently strained, the maximum “useful” nanowall width is chosen such that the alloy layer thickness at the onset of misfit-dislocation formation and the layer thickness giving the maximally inhomogeneous epitaxial strain will approximately coincide. To produce a strong nanopattern-induced elastic effect on dislocation nucleation and glide during the nanoepitaxy, misfit dislocations should begin to glide within the patterned heterostructure as the local layer thickness approaches t˜w/2. The minimum thermodynamic critical layer thickness, h_{c}, for the onset of misfit-dislocation glide for InGaN-alloy growth on a given crystallographic surface can be calculated using a Matthews-Blakeslee-type model (MB model) within the formalism described by Freund and Suresh. See J. W. Matthews and A. E. Blakeslee, J. Cryst. Growth 27, 118 (1974); and L. B. Freund and S. Suresh, Thin Film Materials: Stress, Defect Formation, and Surface Evolution, University Press, Cambridge, 2003) pp. 396-406. The lowermost solid curve in FIG. 4 shows the calculated h_{c} for a second-order inclined-plane slip system in InGaN grown on (0001) GaN. For comparison, the various discrete symbols in the figure show data from a literature survey of studies providing measured InGaN layer thicknesses where misfit dislocations or other evidence of plasticity first appears during typical MOVPE growth of InGaN/GaN. See C. A. Parker et al., Appl. Phys. Lett. 75, 2776 (1999); T. L. Song, J. Appl. Phys. 98, 084906 (2005); S. M. Pereira et al., Adv. Func. Mat. 17, 37 (2007); S. Srinivasan et al., Appl. Phys. Lett. 83, 5187 (2003); M. J. Reed et al., Appl. Phys. Lett. 77, 4121 (2000); G. Ju et al., Appl. Phys. Lett. 110, 262105 (2017); and D. Iida et al., Phys. Stat. Solidi RRL 7, 211 (2013). The hₖ=tₘ=20h_{c} curve (short dashed line) bounds these experiments over a wide range of compositions (0.05<x<0.25), with the ratio hₖ/h_{c}<20 characterizing the maximally delayed introduction of dislocations (beyond the thermodynamic minimum thickness) caused by kinetic limitations on dislocation motion. By equating the elasticity condition of FIG. 3C (t=w/2) and the kinetically delayed plasticity condition of FIG. 4 (t=hₖ=Kh_{c}), the maximum nano-feature-width of interest, wₘ=2Kh_{c}=2tₘ, can be estimated. This maximum kinetic critical thickness is plotted as the uppermost solid curve in FIG. 4 for the specific case of K=20.

As annotated in FIG. 4, the composition-dependent h_{c}(x) and wₘ(x) curves define three strain relaxation regimes of interest for nanopattern design. For large wall widths (above the uppermost solid curve in FIG. 4), w>w_{c}(x), misfit dislocations will enter at thin relative layer thicknesses, t/w, where the strain field remains more-nearly homogeneous due to the quasi-planar local thin-film geometry. Conversely for very small nanowall widths (below the lowermost solid curve in FIG. 4), w<h_{c}(x), misfit-dislocations become unfavorable for all thicknesses, at least for slip systems that can only relieve perpendicular lattice mismatch stresses, and it becomes possible for a purely compliant elastic response to provide perpendicular misfit accommodation (σₓₓ in FIG. 2). For the separate case of nanoposts, the defined regimes still apply, and this last width regime (w<h_{c}) would promote a purely elastic accommodation of all mismatch strain. The present invention is directed in part to the mixed elastic-plastic region within these two bounds, h_{c}(x)<w<2Kh_{c}(x), where a substantial interaction of elastic and plastic behavior can be expected during nanoepitaxy of the InGaN alloy. As an example, for a composition x=0.06, w(0.06)=1 micrometer, and it can be inferred that any InGaN-alloy composition above x=0.06 will require patterned-feature widths having submicron dimensions.

The approaches developed for use in the mixed elastic-plastic region additionally provide a conceptual route to the purely elastic compliancy regime, provided that one can fabricate surface structures with suitably small widths. Indeed, one can realize the hypothetical ideal partitioning of elastic and plastic strain relief in nanowall arrays, as shown the FIG. 2, by fabricating the nanowalls with widths (thicknesses) that approach h_{c}(x). In such cases, it becomes thermodynamically impossible for dislocations to glide on slip systems with misfit-dislocation line directions paralleling the wall orientation, and dislocations will enter on only the pictured slip systems with misfit-dislocation line directions oriented perpendicular to the walls.

### Nanostructure Feature Spacing and Trench Depth

The lateral trench space, s, separating the individual nanostructures not only defines the pitch, p=w+s, and the fill-factor, f=w/p, of the nanopattern;

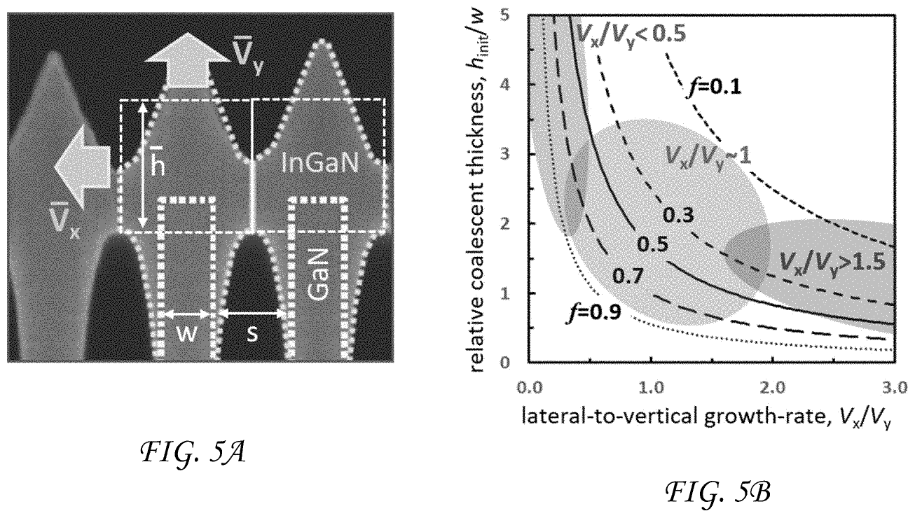

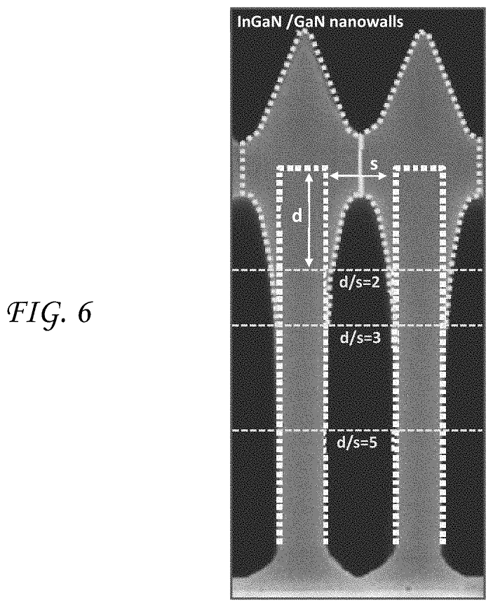

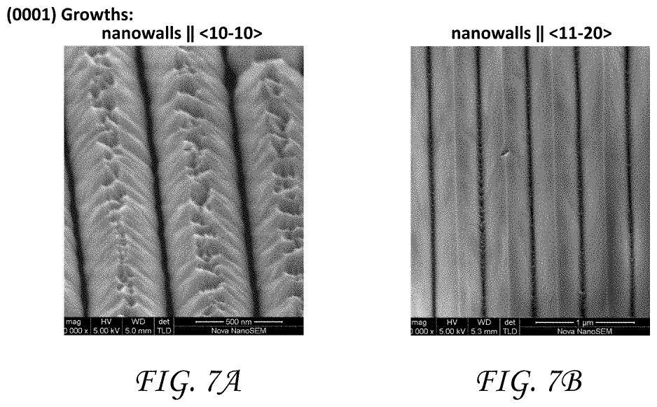

more importantly, it also defines (along with face propagation rates) the nanoshape-averaged, relative film thickness, hᵢₙᵢₜ/w, attainable at the point of coalescence. The normalization by w recognizes that the inhomogeneous elastic strain field will depend on relative nanostructure geometry (or heterostructure shape), and not the absolute thickness. A “rectangular-domain” growth-front propagation model, as shown in FIG. 5A, is assumed to describe growth onto a one-dimensional (1-D) array of flat-topped rectangular walls. To approximately examine how hᵢₙᵢₜ/w depends on s, f, and anisotropic growth rates, the anisotropic growth can be parameterized in terms of two time-averaged growth velocities for growth fronts propagating parallel (with velocity Vₓ) and perpendicular (with velocity V_{y}) to the original substrate surface, and with the coordinate x again taken normal to the walls. The resulting dependence of hᵢₙᵢₜ/w on f and the growth anisotropy, Vₓ/V_{y}, becomes hᵢₙᵢₜ/w=V_{y}/2fVₓ, which is plotted in FIG. 5B.

FIG. 5B places into context previous work to grow patterned III-nitride layers, with CE, ELO, and PE of multi-micron-thick, fully coalesced GaN on sapphire by MOVPE. Such heterostructures fall at the lower-right area of the figure because of their high lateral growth rates (Vₓ/V_{y}>1.5). See C. I. Ashby et al., Appl. Phys. Lett. 77, 3233 (2000); C. I. Ashby et al., U.S. Pat. No. 6,599,362, issued Jul. 29, 2003; K. Hiramatsu et al., Phys. Status Solidi A 176, 535 (1999); B. Beaumont et al., Phys. Status Solidi B 227, 1 (2001); D. B. Thomson et al., J. Nitride Semicond. Res. 4S1, G3.37 (1999); and T. S. Zheleva et al., J. Electron. Mat. 28, L5 (1999). These ELO-based works generally utilize low fill-factor patterns in the regime f<˜0.3.

A closely similar plot for nanopost arrays can be obtained if the 2D array areal fill-factor is redefined as f=w²/p². Thus, previous MBE studies of highly columnar In_{0.5}Ga_{0.5}N nanorods grown by SAE, and thickly stacked InGaN-quantum-dot-in-wire ensembles, can be taken as falling at upper-left area because of their high vertical growth rates (Vₓ/V_{y}<0.5). See S. Fan et al., Appl. Phys. Left. Mat. 4, 076106 (2016); and S. Y. Woo et al., Nanotech. 26, 344002 (2015). This MBE-based work on InGaN alloys, as well as other forms of highly columnar vertical growth such a silicon-germanium “pile growth,” generally utilize high fill-factor patterns in the regime f>˜0.7.

In contrast to these previous works, the present invention is directed to intermediate fill-factors, 0.3<f<0.7, where InGaN MOVPE growth-rates are correspondingly less anisotropic, as shown near the center-left area (0.5<Vₓ/V_{y}<1.5) of FIG. 5B. The selected fill factors facilitate a range of initially coalesced layer thicknesses positioned near 1<hᵢₙᵢₜ/w<3. Because of the strain-field evolution illustrated in FIGS. 3D and 3E, the minimum of the coalescent thickness range can be selected to be just adequate to produce a substantial elastic strain relief, were that the only mechanism to operate. At the same time, however, misfit dislocations will also enter into any layers grown to substantially exceed the kinetic critical thickness. These two coupled mechanisms combine to provide for a nearly complete strain relaxation prior to coalescence. Additionally, design margin exists that can be used to fine-tune the completeness of the strain relaxation by increasing s to increase hᵢₙᵢₜ/w. Importantly, completion of the relaxation prior to coalescence is needed to prevent the recovery of strain as coalescence proceeds.

To reduce misfit-dislocation formation during intentional coalescence, the merging domains should have well-matched lattice parameters (implying attainment of similar alloy compositions during nanoepitaxy). Additionally, to reduce dislocations necessary to accommodate coalescence-induced tilt boundaries, the merging domains should also have the same crystallographic alignment. For end-use applications where coalescence-induced dislocations are especially deleterious (e.g., LEDs for SSL), an alternative approach can be to intentionally stop growth prior to coalescence, thereby eliminating any coalescence-induced dislocations. In this latter embodiment, the strain-relaxed InGaN-alloy template is not a continuous layer; instead, it is a discrete array of submicron or nanometer-scale strain-relaxed InGaN domains. The spacing between these domains can be selected to be large enough that subsequently grown device active regions (if sufficiently thin, as are quantum wells) also do not coalesce, with lateral coalescence only occurring upon growth of a less-defect-sensitive upper contacting layer (should such a laterally continuous, contacting layer be necessary for the chosen application).

To maintain maskless patterned growth at a given pattern's fill-factor, the trenches that separate each nanostructure within the pattern need to have an adequately large depth relative to the pattern spacing, d/s. Specifically, the trench geometry must contain any materials that grow on either the trench-bottoms or the sidewalls in a manner that prevents such growths from propagating upwards to an extent that they interfere with desired materials growing laterally near the topmost portion of the pattern. The trench depth needed for a nanowall array with f near 0.5, or similar, can be measured by fabricating an extremely deep trench with exceptionally vertical sidewalls so that the extent of InGaN sidewall growth during a subsequent InGaN nanoepitaxy run can be directly revealed by cleaving a cross-section of nanowalls and inspecting with SEM imaging. According to FIG. 6, a trench depth as shallow as d=1 s to 2s can be adequate for intermediate fill factors (f=0.3-0.7). Larger relative depths can be used, but at the potential expense of reduced heat transport from powered devices subsequently fabricated on the template.

By limiting the surface structure width as a function of composition, practical limits can be set on the InGaN-alloy nanoepitaxial thickness through subsequent examination of a workable coalescent layer thickness, and through the requirement that the nanoepitaxy utilize only those nanopattern geometries supporting maskless epitaxy. An important primary benefit obtains because the resulting InGaN-alloy film thicknesses needed to realized substantial strain relaxation can be limited to submicron and nanometer thickness compatible with the well-known, tenuous thermal stability of InGaN-alloys, particularly as composition rises to larger InN mole fractions.

### GaN Substrate Orientation

For InGaN growth on nanowall arrays fabricated on polar (0001) GaN, control of the surface morphology unavoidably drives selection of the in-plane crystallographic orientation of the nanowall array. Past work performing CE and ELO of GaN utilized striped-mask openings or etched-walls that are typically oriented lengthwise parallel to <10-10> GaN; subsequent manipulation of the GaN growth conditions (primarily temperature) was used to alter the favored growth facets and their growth rates such that the initial patterned stripes eventually coalesced to form planar GaN. As shown in FIG. 7A, InGaN nanoepitaxy onto <10-10>-oriented nanowalls instead produces a very roughly serrated, pyramidal surface, where the {11-21} sidewalls imposed by the nanopattern orientation compete with the InGaN-alloy's strong tendency (under chemical vapor-phase growth) to form {10-11} facets. These same preferred facets also appear as the V-defect pits that chaotically appear at the apex of the <10-10>-aligned nanowalls in FIG. 7A. Unlike in GaN, the preferred {10-11} growth facets of InGaN alloys cannot be easily suppressed by temperature, because temperature strongly controls the needed alloy composition.

A workable solution to this morphology problem can be found by reorienting the GaN nanowalls along the less typical <11-20> direction, thereby taking advantage of the fact that extended, highly stable {10-11} facets will inevitably result during InGaN-alloy nanoepitaxy onto such a pattern. FIG. 7B shows the resultant surface morphology, where overall, the surface consists of an ideal array of pyramidal nanowalls/stripes, with each wall having a pair of bounding {10-11} upper facets, and with the facets extending the entire length of the original nanowall. As seen by scanning electron microscopy (SEM) and scanning transmission electron microscopy (STEM), these facets are locally very flat. This local flatness suffices for subsequent growth of optoelectronic-device active regions, such as quantum wells or light-absorbing layers, although at the cost of accommodating the accompanying nanopyramidal surface corrugation within the overall device-processing and device-design scheme.

Alternatively, semipolar or nonpolar GaN substrates can be used and the nanopatterns can be comprise either an array of nanowalls or an array of nanoposts. In the case of nanowall arrays, the nanowalls can be (i) bounded by sidewall surfaces that are orthogonally oriented to the (0001) planes of the GaN substrate, or the nanowalls can instead be (ii) oriented orthogonally to the aforementioned case, such that the crystallographic line-direction lying along the tops of the walls also lies parallel to the (0001) planes of the GaN substrate. These two orientations of the nanowall planes place the first-order basal-plane dislocation-slip system of GaN such that c-plane misfit-dislocation glide correspondingly occurs either (i) transverse to the wall, as pictured in FIGS. 2A-C, or (ii) parallel to the wall.

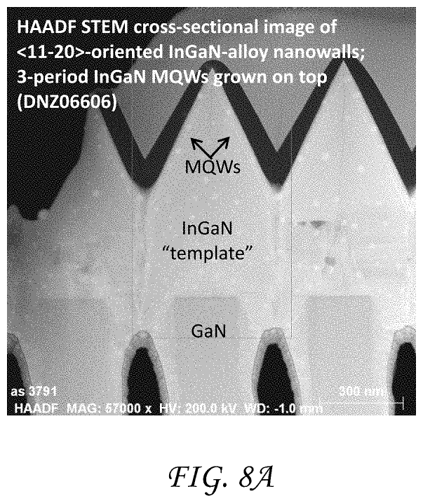

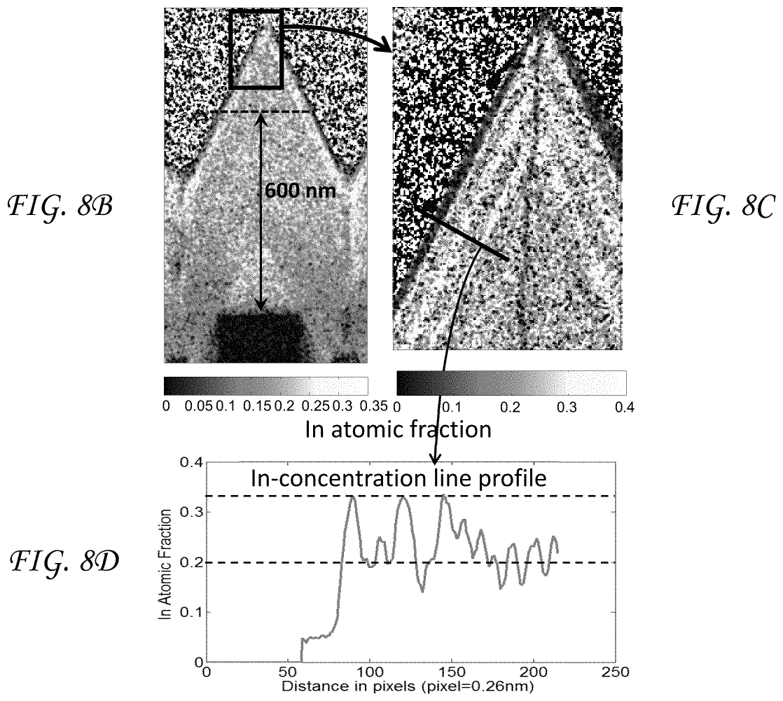

In addition to selecting the slip-system orientations, the use of semipolar and nonpolar nanoepitaxy geometries can offer a means of selecting the cross-sectional shape of the InGaN alloy grown on the GaN surface structures. For instance, nanoepitaxy of InGaN-alloys onto GaN nanowalls fabricated on the semipolar (20-25) surface of GaN, with the walls oriented per case (i) just above, produces flat-topped InGaN alloy growths instead of the pyramidal growths seen in FIGS. 7B and 8A. Because the same growth conditions were used for the nanowalls on polar and semipolar GaN, it can be inferred that the resulting differences in nanoepitaxial shape arise from selecting the crystallographic orientations of the GaN surface and the nanopatterns thereon.

### Strain Relaxation and Average Composition

To assess strain and composition by X-ray diffraction (XRD), the average strain within the partially strain-relaxed InGaN-alloy nanopyramidal stripes was assumed to produce a distorted unit cell with orthorhombic structure. This assumed structure arises from the fact that the hexagonal structure of the unstrained wurtzite InGaN alloy can itself be rewritten in a formally orthorhombic form known as “orthohexagonal.” See C. Hammond, Introduction to Crystallography, Revised Edition (Oxford University Press, New York, 1992) pp. 65-66. Once unequal in-plane strains are applied by the nanowall epitaxy and subsequent strain relaxation process, the resultant deformed orthohexagonal structure becomes formally orthorhombic, assuming that any small shear deformations that would further lower the lattice symmetry can be neglected. Under the assumption of orthorhombic structure, the InGaN-alloy unit cell lattice parameters can be determined by measuring a minimum of three properly chosen XRD reflections. The composition and strain can then be calculated from the measurements by considering the elastic deformations in a manner described by Schuster, but in a modified form that accounts for the lack of purely biaxial in-plane applied strains, this latter case being the standard assumption that is applied to conventional planar heteroepitaxy of lattice-mismatched InGaN onto (0001) GaN. See M. Schuster et al., J. Phys. D: Appl. Phys. 32, A56 (1999).

The specific reflections used were symmetric (0002) or (0004), which gives the orthorhombic c lattice parameter; asymmetric (20-25), which gives the in-plane orthorhombic lattice parameter perpendicular to the nanowall plane; and asymmetric (11-24), which gives the in-plane orthorhombic lattice parameter parallel to the nanowalls. Notably, the asymmetric XRD reflection intensities in these samples are especially weak and broad due to the intentionally arranged inhomogeneous elastic strain and the high misfit-dislocation content driven by that strain. Nonetheless, limited measurements were successfully made on selected thicker InGaN samples grown up to and beyond the point of coalescence. These measurements find InGaN-alloy template compositions of x=0.21 and a high degree of strain relaxation (80-90%), with the stated range reflecting a small asymmetry in the strain relief for in-plane directions parallel and perpendicular to the nanowalls. Notably, the expected composition for a thin, pseudomorphic, InGaN-alloy grown on planar GaN under the same MOVPE conditions would give x=0.14. Thus, the strain relaxed nanoepitaxy is successfully raising the composition by ˜1.5x.

### STEM/EDS Compositional Maps and Defect Structure

FIG. 8A is a cross-sectional scanning-transmission electron microscopy image of a 600-nm-thick InGaN buffer and 3-period InGaN MQW grown on a <11-20>-oriented GaN nanowall. High-resolution atomic-scale TEM imaging of this same sample (not shown) finds misfit-dislocations that have line directions running parallel to the topmost horizontal plane of the GaN nanowalls, with the misfit cores located just below the GaN/InGaN heterointerface. This unusual location is thought to be driven by the highly inhomogeneous strain that will be present at the onset of dislocation, where the complex sharing of lattice deformations between the nanostructured GaN and InGaN causes equilibrium misfit-dislocation positions that differ from the ideal interfacial position expected for planar heteroepitaxy onto a thick wafer.

The indium composition of the alloy varies spatially during the early stage of growth onto the nanopattern, with In-rich (x˜0.25) growth appearing within the initial pyramidal domain that forms just above each nanowall at the beginning of growth, with In-poor (x˜0.15) domains forming lateral to these initial pyramids, and in the lower coalescent-front regions of the layer. As seen in FIG. 8B, the composition difference between these two laterally adjacent domains is significant, approaching Δx˜0.10 or more. As growth progresses beyond the point of coalescence, the resulting upper half of the layer takes on a much more uniform, and higher composition (x˜0.25). Defects are not generally seen in the upper half of the layer, with the main exception being the region below the v-shaped pyramidal valleys where any dislocations formed at the time of coalescence may propagate upwards to thread the surface. Such dislocations can be avoided entirely if one opts for an uncoalesced template.

FIG. 8C shows the 3-period InGaN MQWs grown on the coalesced InGaN layer to probe the optical properties enabled by the strain-relaxed template. As shown in FIG. 8D, EDS measurements find QW compositions x=0.33 for growth conditions that would otherwise yield a composition of x=0.20 for planar MQW growth. The resulting enhancement of the QW composition, 1.65x, is similar to that already noted for the bulk-like strain-relaxed InGaN-alloy template layer. The results again confirm the expected increase in In incorporation that occurs when InGaN is grown with reduced epitaxial strain. Notably, the QWs exhibit significant variations in thickness with lateral positions along the upper facets of the pyramidal template, with the effect being strongest nearest the apexes (as shown in FIG. 8C) and valleys (not shown at high mag.) of the layer. The grainy appearance of the EDS-composition maps results from signal-limited counting statistics, and the resulting image noise makes it quite difficult to evaluate the actual abruptness of the well-barrier interfaces. As shown in FIG. 8A, higher-spatial resolution HAADF images show relatively abrupt interfaces that are quite unlike the poorly defined, noise-limited interfaces seen in FIG. 8C. Such images also confirm the already noted modulation of the well thickness that is visible irrespective of the noise. These diagnostic-QW growths utilize conditions previously optimized for planar-grown LEDs; thus, substantial improvement of the MQW structural quality is possible.

### Room-Temperature Photoluminescence and Radiative Efficiency

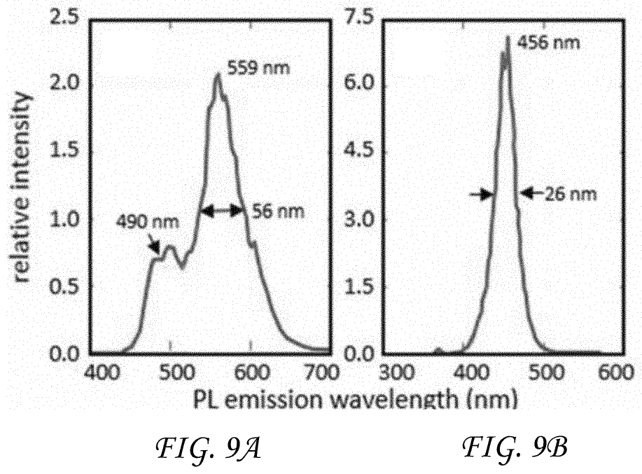

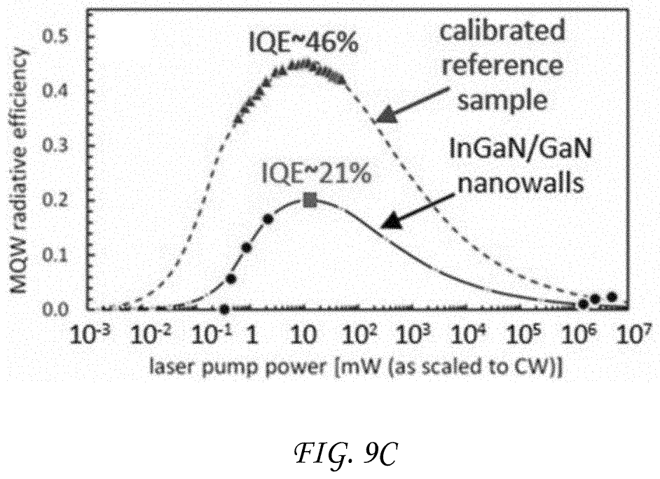

FIGS. 9A and 9B show photoluminescence (PL) spectra of the optical properties of the MQWs grown on the strain-relaxed InGaN-alloy templates. As seen in FIG. 9A, intense MQW emission at 559 nm with a FWHM of 56 nm is readily attained when pumping the sample at 325 nm and 0.6 mW. The weaker 490 nm shoulder peak corresponds to the bulk-InGaN band-gap of an alloy with composition near x=0.24. See J. Wu et al., Appl. Phys. Lett. 80, 4741 (2002). Thus, this secondary peak is attributed to nonselective pumping of the InGaN barriers and the upper region of the InGaN-alloy template, as both domains have compositions that would emit near this wavelength, as already seen by XRD and STEM/EDS. For comparison, in FIG. 9B is shown the PL spectrum for an identically pumped 5-MQW blue-emitting reference sample that has a calibrated, well-established radiative efficiency of ˜46%. The total integrated PL-peak intensity FIG. 9B is less than 2× that of FIG. 9A. Additional MQWs with spectral emission extending to wavelengths as long as 610 nm, though typically with a broader ˜100 nm FWHM, have been attained through experimental variations of the InGaN template's composition, thickness, strain state, and associated growth conditions.

FIG. 9C shows a measurement of the radiative efficiency of the InGaN-alloy template MQWs emitting in FIG. 9A. Each of the measured efficiencies (circles) are computed as the ratio of the integrated PL intensity of the unknown and the reference samples, with the pump power varied by selecting the pump laser and its incident-beam attenuation. The integrated intensities omit the intensity due to any identifiable non-MQW emission, and moderate estimated corrections are applied to the intensity ratios to account for differences in absorption and transport that arise from unavoidable differences in the MQW-region structure and composition of the unknown and reference samples. To facilitate a fully quantitative interpretation of the data, a modified ABC-type carrier recombination model is fitted (dashed line) to the calibrated room-temperature PL intensity data (triangles) separately taken for the reference sample. See G. B. Lin et al., Appl. Phys. Lett. 101, 241104 (2012); and J. I. Shim, in III-Nitride Based Light Emitting Diodes and Applications, T.-Y. Seong et al., Eds. (Springer, Heidelberg, 2013) pp. 170-190. This fitting model for the reference standard establishes a unique empirical relationship between radiative efficiency, carrier density, and absorbed pump-power. The fitted carrier recombination model for the standard then allows the measured intensity-ratios of the unknown to be determined as radiative efficiencies through intensity-ratio-scaling of the fitted curve at each measurement power. The resulting measurements are independently fitted to a second radiative-recombination-model curve to capture the overall power-dependent radiative-efficiency of the InGaN-template-MQW sample (dash-dot line). As seen in the figure, the peak radiative efficiency for the 560-nm-emitting MQW sample is thereby estimated to be ˜21% (square).

This reference-standard-based approach avoids lengthy low-temperature PL studies of the efficiency (excepting the one-time, temperature- and power-dependent investigation required for characterizing the standard) and thus allows the routine estimation of the radiative efficiency of all diagnostic-MQW samples of interest. A second advantage of this approach is that any “promising-looking” temperature-dependent emission arising from long-wavelength-emitting defects cannot possibly be mistaken for band-edge emission, because no temperature dependence is used (excepting the calibrated reference, which is conventional, well-understood material), and because even very strong defect emission will pale in intensity when quantitatively compared to a band-edge-emitting MQW standard of known, reasonably high, radiative efficiency. See M. A. Reshchikov and H. Morkoc, J. Appl. Phys. 97, 061301 (2005).

For partially and fully strain-relaxed InGaN-alloy templates, peak radiative efficiencies of samples emitting from 550-560 nm under 325-nm excitation is 10-30%. For similar samples but emitting from 585-610 nm under 325-nm excitation, peak radiative efficiencies are ˜5-20%. For InGaN-alloy template samples pumped at lower power densities using the 325-nm laser (e.g., the left four measurements shown as circles in FIG. 9C), there is almost no observable shift in the emission-wavelength with power. When these samples are pumped using the high peak-power-density pulsed 266 nm laser (e.g., the right three circles in FIG. 9C), the emission peaks blue-shift by ˜10-30 nm relative to the 325-nm excitation, with the longest-emitting samples and the highest-power 266-nm excitation exhibiting the largest shifts, as expected. It is noted that light-extraction efficiencies can differ for the planar reference-MQW sample versus the 1D nanopyramidal-MQW samples. No corrections have been applied to account for these possible differences.

The present invention has been described as a strain-relaxed InGaN-alloy template. It will be understood that the above description is merely illustrative of the applications of the principles of the present invention, the scope of which is to be determined by the claims viewed in light of the specification. Other variants and modifications of the invention will be apparent to those of skill in the art.

I claim:

1. An InGaN-alloy template, comprising an InₓGa₁₋ₓN-alloy template layer grown on a nanopatterned GaN substrate.

2. The InGaN-alloy template of claim 1, wherein x is between 0.06 and 0.6.

3. The InGaN-alloy template of claim 2, wherein x is between 0.15 and 0.4.

4. The InGaN-alloy template of claim 1, wherein the nanopatterned GaN substrate comprises a bulk GaN substrate or III-nitride film pregrown on a substrate.

5. The InGaN-alloy template of claim 1, wherein the nanopatterned GaN substrate comprises polar (0001) GaN.

6. The InGaN-alloy template of claim 5, wherein the nanopatterned GaN substrate comprises a nanopattern with <11-20>-oriented nanowalls.

7. The InGaN-alloy template of claim 1, wherein the nanopatterned GaN substrate comprises semipolar GaN.

8. The InGaN-alloy template of claim 7, wherein the nanopatterned GaN substrate comprises a nanopattern with nanowalls that are oriented orthogonal to the (0001) planes of the GaN substrate.

9. The InGaN-alloy template of claim 7, wherein the nanopatterned GaN substrate comprises a nanopattern with nanowalls that are oriented parallel to the (0001) planes of the GaN substrate.

10. The InGaN-alloy template of claim 1, wherein the nanopatterned GaN substrate comprises nonpolar GaN.

11. The InGaN-alloy template of claim 10, wherein the nanopatterned GaN substrate comprises a nanopattern with nanowalls are oriented orthogonal to the (0001) planes of the GaN substrate.

12. The InGaN-alloy template of claim 10, wherein the nanopatterned GaN substrate comprises a nanopattern with nanowalls that are oriented parallel to the (0001) planes of the GaN substrate.

13. The InGaN-alloy template of claim 1, wherein the nanopatterned GaN substrate comprises a periodic array of surface structures, wherein the surface structures have a width, wherein the surface structures are spaced apart by a trench having a depth, and wherein the width of the surface structures and the spacing between the surface structures define a fill factor of the periodic array.

14. The InGaN-alloy template of claim 13, wherein the surface structures comprise nanowalls or nanoposts.

15. The InGaN-alloy template of claim 13, wherein the width of the surface structures and the thickness of the InₓGa₁₋ₓN-alloy template layer are selected to relax the strain in the InₓGa₁₋ₓN alloy.

16. The InGaN-alloy template of claim 15, wherein the width of the surface structures is less than twice a kinetically limited critical thickness of the InGaN alloy.

17. The InGaN-alloy template of claim 15, wherein the width of the surface structures is less than one micron.

18. The InGaN-alloy template of claim 15, wherein the thickness of the InₓGa₁₋ₓN-alloy template layer is greater than the width of the surface structures.

19. The InGaN-alloy template of claim 18, wherein the thickness of the InₓGa₁₋ₓN-alloy template layer is greater than the twice the width of the surface structures.

20. The InGaN-alloy template of claim 13, wherein the fill factor of the periodic array is between 0.3 and 0.7.

21. The InGaN-alloy template of claim 13, wherein the depth of the trench is greater than the spacing between the surface structures.

22. The InGaN-alloy template of claim 1, wherein the InₓGa₁₋ₓN-alloy template layer is uncoalesced on the nanopatterned GaN substrate.

23. The InGaN-alloy template of claim 1, wherein the InₓGa₁₋ₓN-alloy template layer is coalesced on the nanopatterned GaN substrate.

24. A method for fabricating an InGaN-alloy template, comprising:
nanopatterning a GaN substrate, and
maskless nanoepitaxially growing an InGaN-alloy template layer onto the nanopatterned GaN substrate.

25. The method of claim 24, further comprising growing a lattice-matched InGaN alloy on the InGaN-alloy template layer.

26. The method of claim 25, wherein the growing a lattice-matched InGaN alloy comprises a high-growth-rate method.

27. The method of claim 26, wherein the high-growth-rate method comprises hydride vapor-phase epitaxy or amonothermal crystal growth.

28. The method of claim 25, further comprising removing the GaN substrate to provide a free-standing wafer of InGaN alloy.

29. The method of claim 24, further comprising growing an InGaN-alloy multiple quantum well structure or an InGaN-alloy-containing epitaxial optoelectronic-device structure on the InGaN-alloy template layer.
